(19) United States
(12) Patent Application Publication
(10) Pub. No.: US 2026/0068608 A1
(43) Pub. Date: Mar. 5, 2026

(54) INNER SPACER RELIABILITY EVALUATION

(71) Applicant: International Business Machines Corporation, Armonk, NY (US)

(72) Inventors: Huimei Zhou, Albany, NY (US); Jun Liu, Clifton Park, NY (US); Ravikumar Ramachandran, Pleasantville, NY (US); Kai Zhao, Albany, NY (US); Miaomiao Wang, Albany, NY (US)

(21) Appl. No.: 18/816,120

(22) Filed: Aug. 27, 2024

(51) Int. Cl. H01L 21/66

(52) U.S. Cl. CPC H01L 22/30

(57) ABSTRACT

A simulated inner spacer reliability evaluation component includes a substrate having a surface, at least one pedestal coupled to the surface of the substrate, at least one pinched off simulated inner spacer coupled to the at least one pedestal, and a metal layer coupled to the at least one pinched off simulated inner spacer. The at least one pinched off simulated inner spacer defines at least one indent located above the at least one pedestal.

### BACKGROUND

The present disclosure relates to the electrical, electronic, and computer fields. In particular, the present disclosure relates to evaluation of inner spacer reliability for gate-all-around nanosheet architectures.

As the silicon sheet to silicon sheet spacing (Tsus) in gate all around (GAA) field effect transistor (FET) architectures is reduced, the reliability of each inner spacer (IS) between nanosheets (NS) becomes more important. In particular, there is less room for a thicker IS to inhibit breakdown (BD) mix.

### SUMMARY

Embodiments of the present disclosure include structures and fabrication methods for inner spacer reliability evaluation in gate-all-around nanosheet architecture.

Embodiments of the present disclosure include a simulated inner spacer reliability evaluation component. The component includes a substrate having a surface. The component further includes at least one pedestal coupled to the surface of the substrate. The component further includes at least one pinched off simulated inner spacer coupled to the at least one pedestal where the at least one pinched off simulated inner spacer defines at least one indent located above the at least one pedestal. The component further includes a metal layer coupled to the at least one pinched off simulated inner spacer. The component can further include a dielectric layer coupled to the surface of the substrate and adjacent to both the at least one pedestal and the at least one pinched off simulated inner spacer. The component can further include where the dielectric layer comprises SiO₂. The component can further include an insulator layer coupled to the dielectric layer and adjacent to the metal layer. The component can further include wherein the insulator layer comprises SiBCN. The component can further include wherein the pinched off simulated inner spacer comprises SiN. The component can further include wherein the pedestal comprises SiGe. The component can further include wherein the metal layer comprises tungsten. The component can further include wherein the at least one pedestal comprises a work function metal and at least a portion of the work function metal is coated with a high K dielectric. The component can further include a doped a-Si layer located between the at least one pinched off simulated inner spacer and the metal layer. The component can further include wherein at least a portion of the at least one pinched off simulated inner spacer is in contact with the insulator layer. The component can further include wherein the pedestal comprises SiGe and the metal layer is at least partially coated with a high K dielectric.

Additional embodiments of the present disclosure include a method for forming a simulated inner spacer reliability evaluation component. The method further includes providing a substrate having a surface and a pedestal layer coupled to the surface of the substrate. The method further includes patterning the pedestal layer. The method further includes depositing a dielectric layer on the surface of the substrate, wherein the dielectric layer is adjacent the patterned pedestal layer. The method further includes etching back the patterned pedestal layer to form at least one pedestal. The method further includes depositing a simulated inner spacer layer on both the dielectric layer and the etched back patterned pedestal layer. The method further includes etching back the simulated inner spacer layer, wherein the etched back simulated inner spacer layer comprises at least one pinched off simulated inner spacer defining at least one indent located above the at least one pedestal. The method further includes depositing an insulating layer on both the dielectric layer and the at least one pinched off simulated inner spacer. The method further includes patterning the insulating layer to expose the at least one pinched off simulated inner spacer. The method further includes depositing a metal layer above the exposed at least one pinched off simulated inner spacer. The method can further include wherein the at least one pedestal comprises a work function metal and at least a portion of the work function metal is coated with a high K dielectric. The method can further include depositing a doped a-Si layer above the exposed at least one pinched off simulated inner spacer before depositing the metal layer above the exposed at least one pinched off simulated inner spacer. The method can further include wherein at least a portion of the at least one pinched off simulated inner spacer is in contact with the insulator layer. The method can further include wherein the pedestal comprises SiGe and the metal layer is at least partially coated with a high K dielectric. The method can further include connecting a wiring pad to the metal layer for electrical testing of the at least one pinched off simulated inner spacer.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

FIG. 1 illustrates a flow diagram of an exemplary method that can be implemented in accordance with embodiments of the present disclosure.

FIGS. 2A-2C illustrate views of an example of a component following the performance of a portion of the example method of FIG. 1, in accordance with embodiments of the present disclosure.

FIGS. 3A-3D illustrate views of an example of a component following the performance of a portion of the example method of FIG. 1, in accordance with embodiments of the present disclosure.

FIGS. 4A-4D illustrate views of an example of a component following the performance of a portion of the example method of FIG. 1, in accordance with embodiments of the present disclosure.

FIGS. 5A-5D illustrate views of an example of a component following the performance of a portion of the example method of FIG. 1, in accordance with embodiments of the present disclosure.

FIGS. 6A-6D illustrate views of an example of a component following the performance of a portion of the example method of FIG. 1, in accordance with embodiments of the present disclosure.

FIGS. 7A-7D illustrate views of an example of a component following the performance of a portion of the example method of FIG. 1, in accordance with embodiments of the present disclosure.

FIGS. 8A-8D illustrate views of an example of a component following the performance of a portion of the example method of FIG. 1, in accordance with embodiments of the present disclosure.

FIGS. 9A-9D illustrate views of an example of a component following the performance of a portion of the example method of FIG. 1, in accordance with embodiments of the present disclosure.

FIGS. 10A-10D illustrate views of an example of a component following the performance of a portion of the example method of FIG. 1, in accordance with embodiments of the present disclosure.

FIGS. 11A-11D illustrate views of an example of a component following the performance of a portion of the example method of FIG. 1, in accordance with embodiments of the present disclosure.

FIGS. 12A-12B illustrate views of wiring for electrical testing and the component of FIG. 11A-11D, in accordance with embodiments of the present disclosure.

FIGS. 13A-13D illustrate views of components that are alternative embodiments compared to the component of FIG. 11A-11D, in accordance with embodiments of the present disclosure.

### DETAILED DESCRIPTION

Aspects of the present disclosure relate generally to the electrical, electronic, and computer fields. In particular, the present disclosure relates to semiconductor devices, especially read only memory. While the present disclosure is not necessarily limited to such applications, various aspects of the disclosure may be appreciated through a discussion of various examples using this context.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B”are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

The processes, steps, and structures described below do not form a complete process flow for manufacturing integrated circuits. The disclosure can be practiced in conjunction with integrated circuit fabrication techniques currently used in the art, and only so much of the commonly practiced process steps are included as necessary for an understanding of the different examples of the present disclosure. Many of the figures represent cross sections of a portion of an integrated circuit during fabrication and are not drawn to scale, but instead are drawn so as to illustrate different illustrative features of the disclosure.

In general, the various processes for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE, the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

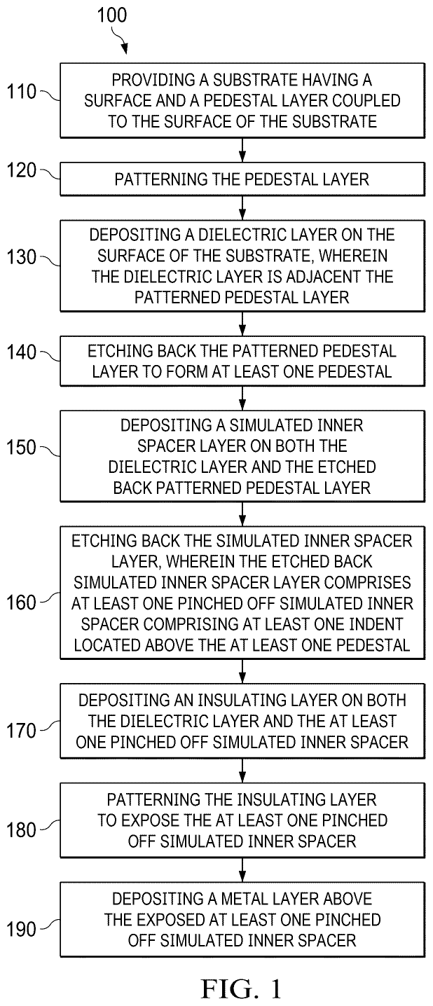

FIG. 1 shows flowchart 100 illustrating steps for forming an embodiment of a simulated inner spacer reliability evaluation component. Step 110 includes providing a substrate having a surface and a pedestal layer coupled to the surface of the substrate. Step 120 includes patterning the pedestal layer. Step 130 includes depositing a dielectric layer on the surface of the substrate, wherein the dielectric layer is adjacent the patterned pedestal layer. Step 140 includes etching back the patterned pedestal layer to form at least one pedestal. Step 150 includes depositing a simulated inner spacer layer on both the dielectric layer and the etched back patterned pedestal layer. Step 160 includes etching back the simulated inner spacer layer, wherein the etched back simulated inner spacer layer comprises at least one pinched off simulated inner spacer comprising at least one indent located above the at least one pedestal. Step 170 includes depositing an insulating layer on both the dielectric layer and the at least one pinched off simulated inner spacer. Step 180 includes patterning the insulating layer to expose the at least one pinched off simulated inner spacer. Step 190 includes depositing a metal layer above the exposed at least one pinched off simulated inner spacer.

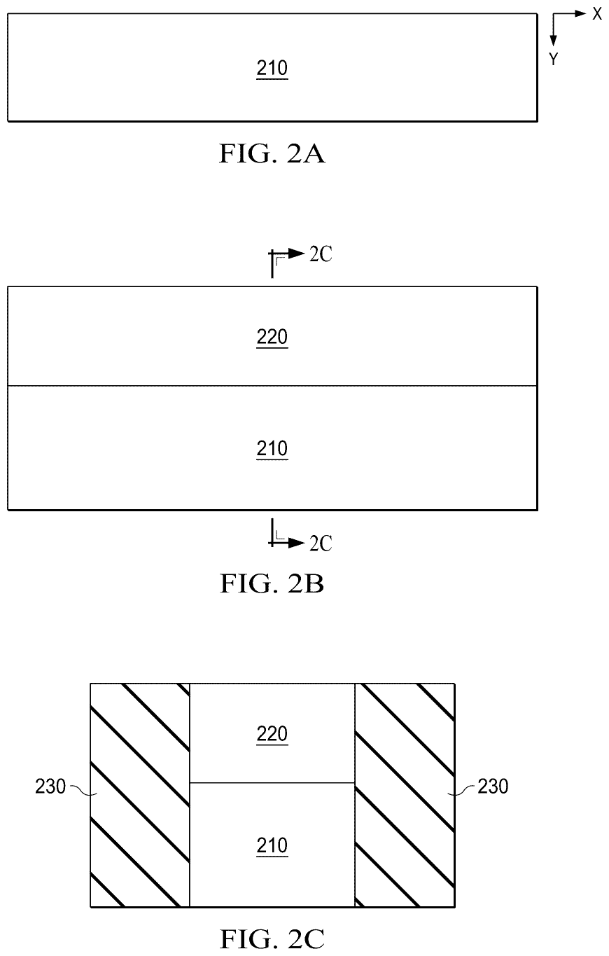

FIGS. 2A-2C show active area patterning of pedestal layer 220 and substrate 210. FIG. 2A is a top down view. FIGS. 2B-2C are cross section views. Substrate 210 has a top surface and pedestal layer 220 is coupled to the top surface. In this sub-generic example, substrate 210 comprises silicon and pedestal layer 220 comprises silicon germanium. Dielectric layer 230 is deposited on a surface of substrate 210 and is adjacent pedestal layer 220. In this example, dielectric layer 230 comprises silica (SiO₂). Of course, embodiments of this disclosure are not limited to this sub-generic example or to the particular materials described for the different sub-components.

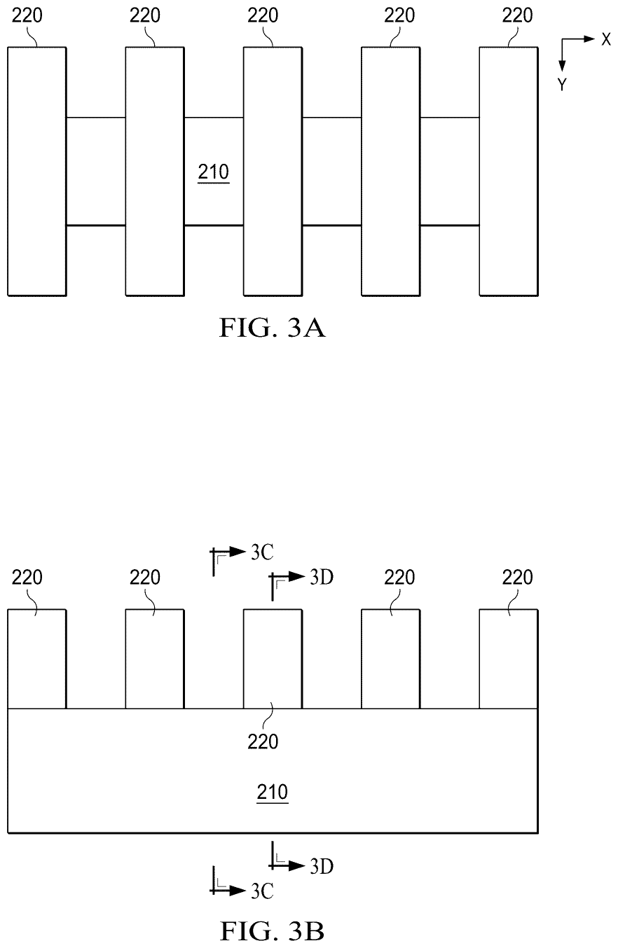

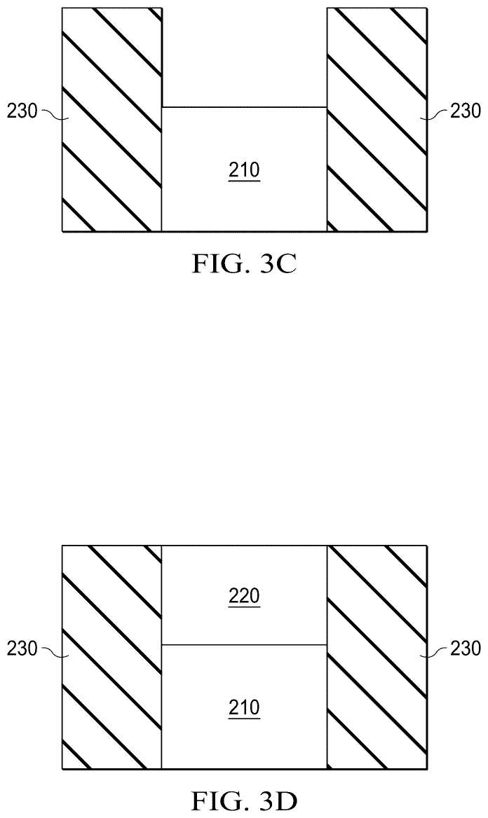

FIGS. 3A-3D show gate (PC) patterning of pedestal layer 220. FIG. 3A is a top down view. FIGS. 3B-3D are cross section views. Pedestal layer 220 is patterned down to substrate 210. Dielectric layer 230 is unaffected.

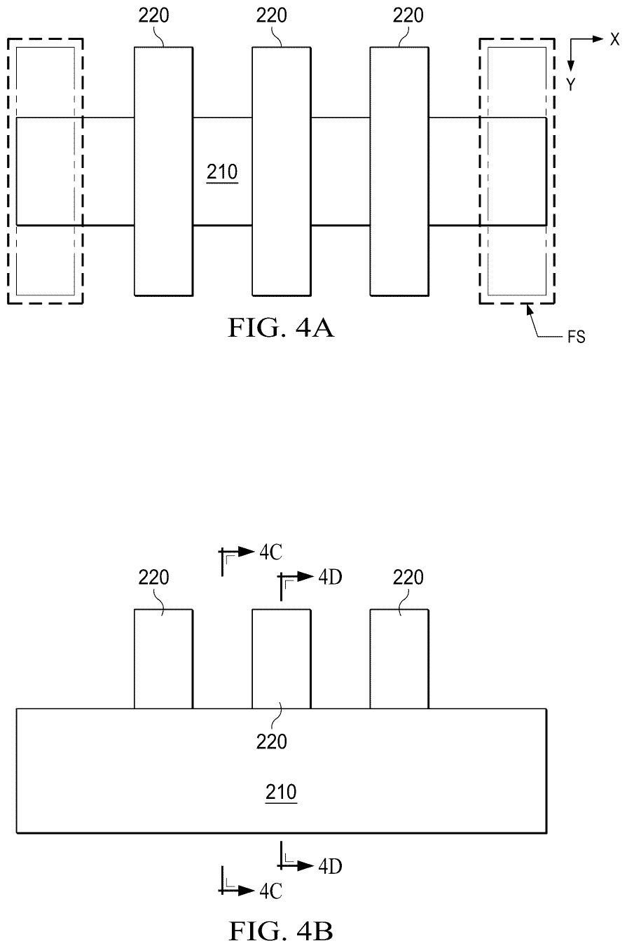

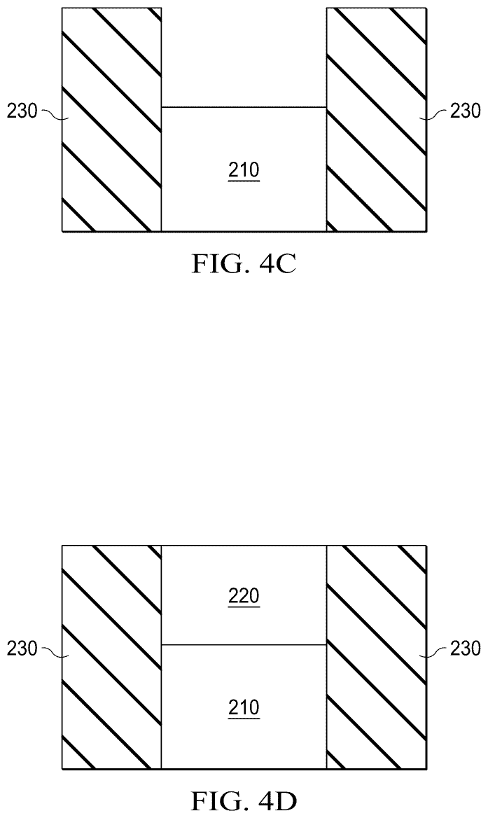

FIGS. 4A-4D show Fin cut mask (FS) patterning of pedestal layer 220. The mask is used to cut edge the SiGe of pedestal layer 220. FIG. 4A is a top down view. FIGS. 4B-4D are cross section views. A subset of pedestals are removed.

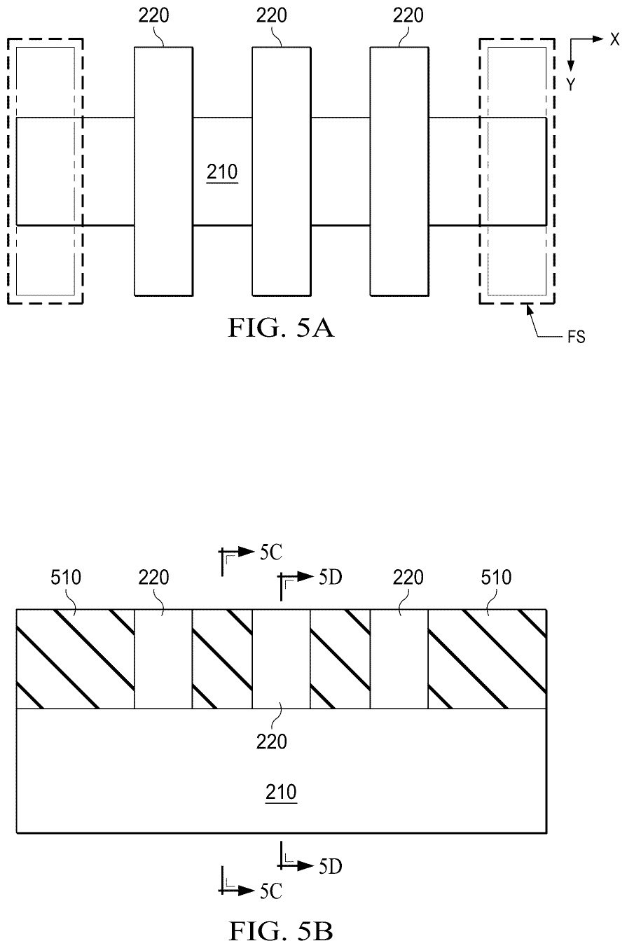

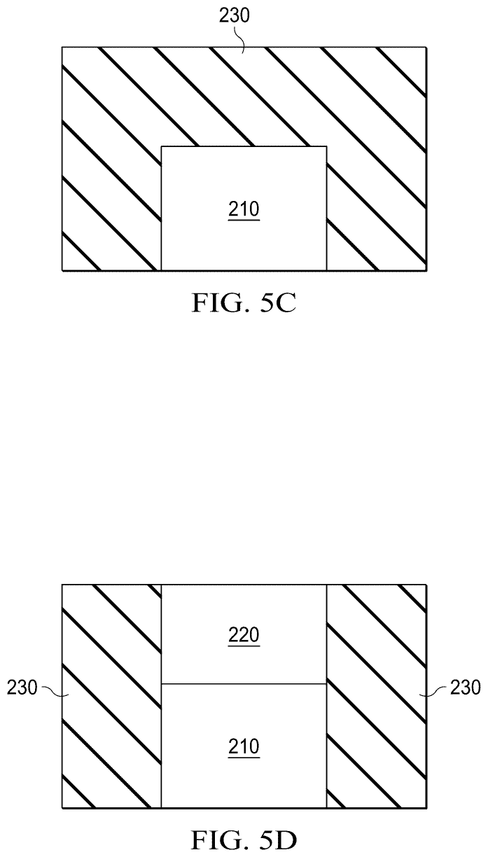

FIGS. 5A-5D show more SiO₂ deposition 510. FIG. 5A is a top down view. FIGS. 5B-5D are cross section views. The spaces between the pedestals are filled with SiO₂.

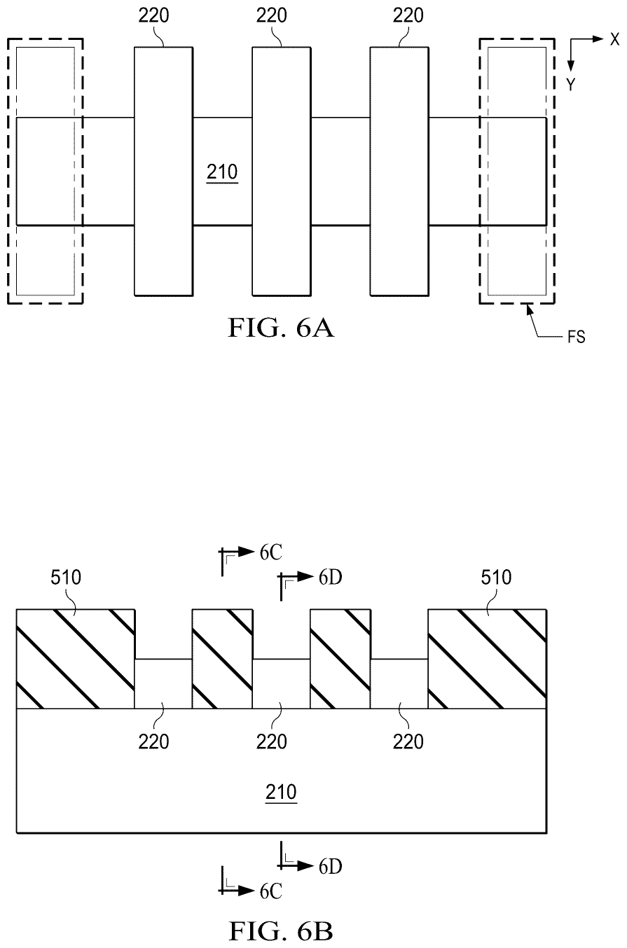

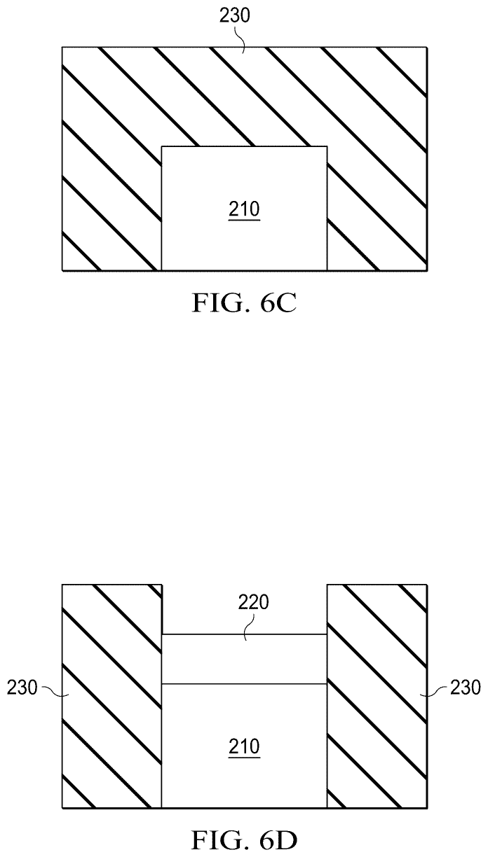

FIGS. 6A-6D show SiGe indenting of pedestal layer 220. FIG. 4A is a top down view. FIGS. 6B-6D are cross section views. The height of the pedestals is lowered (indented) beneath the level of dielectric layer 230.

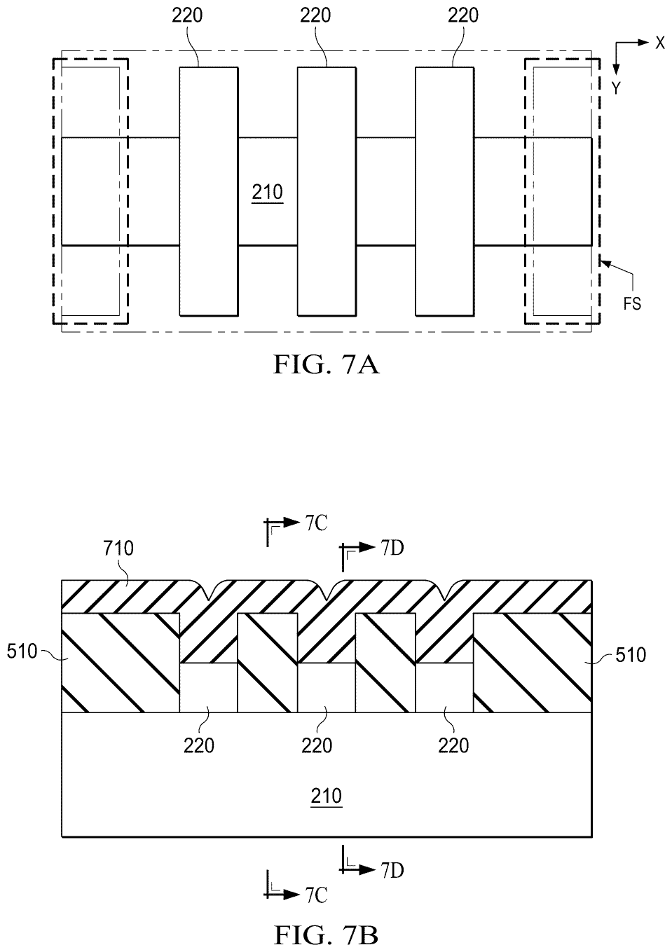

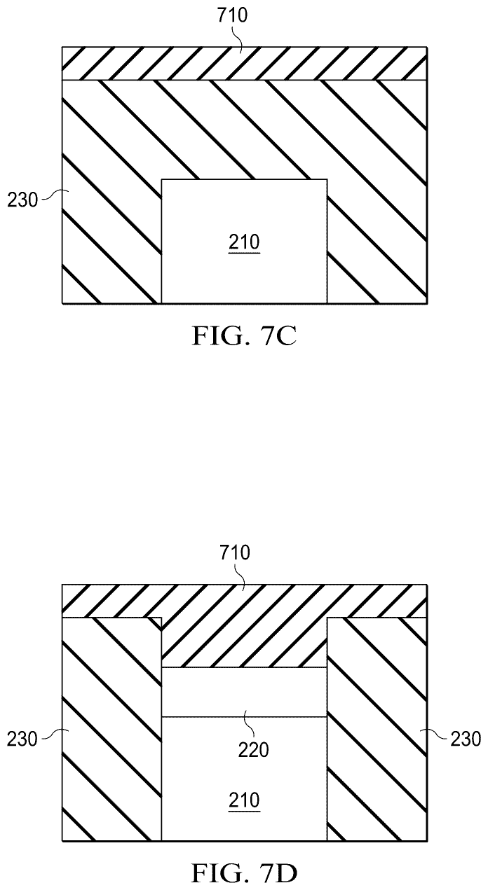

FIGS. 7A-7D show inner spacer fill by deposition of simulated inner spacer layer 710. FIG. 7A is a top down view. FIGS. 7B-7D are cross section views. Simulated inner space layer 710 defines an indent above each pedestal that is caused by the lowered height of each pedestal relative to the level of the dielectric layer 230.

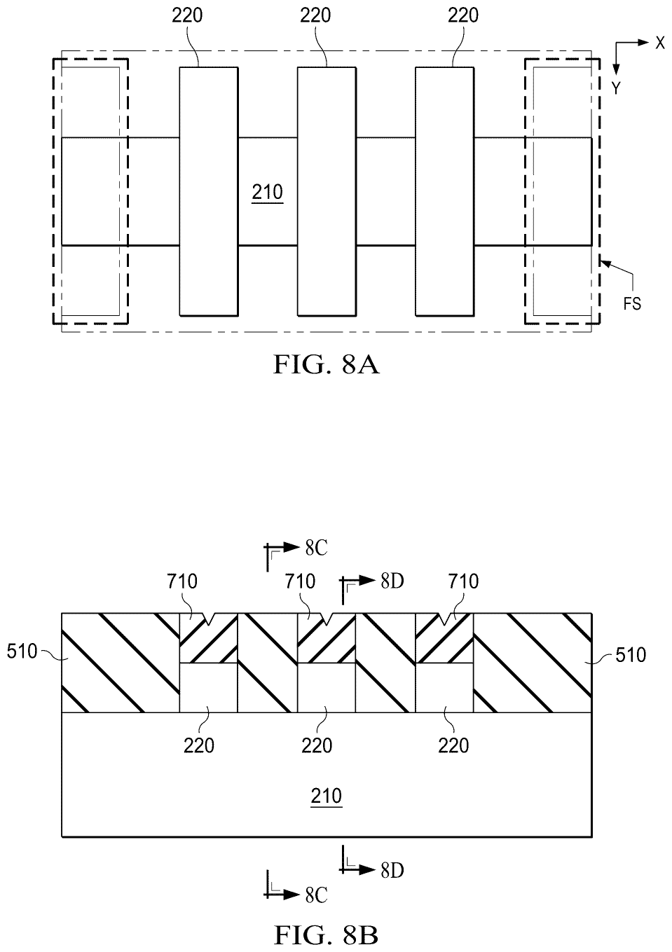

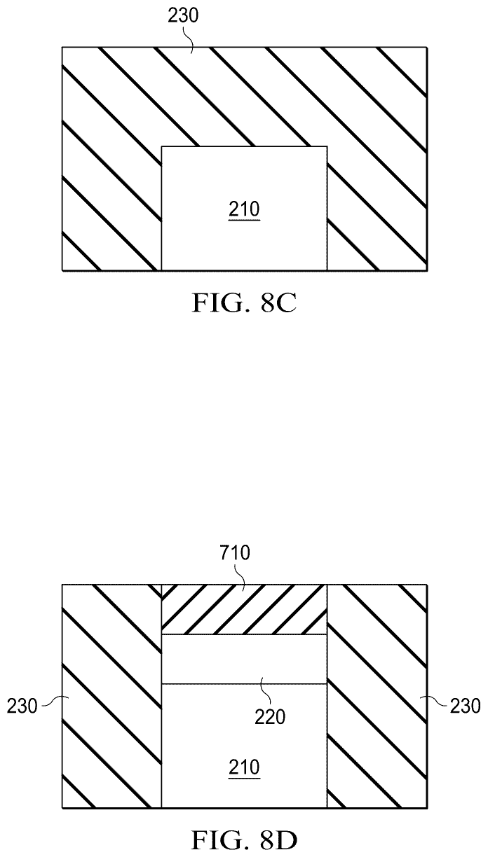

FIGS. 8A-8D show etching back of simulated inner spacer layer 710. FIG. 8A is a top down view. FIGS. 4B-4D are cross section views. The indent above each pedestal is maintained as simulated inner spacer layer 710 is etched back.

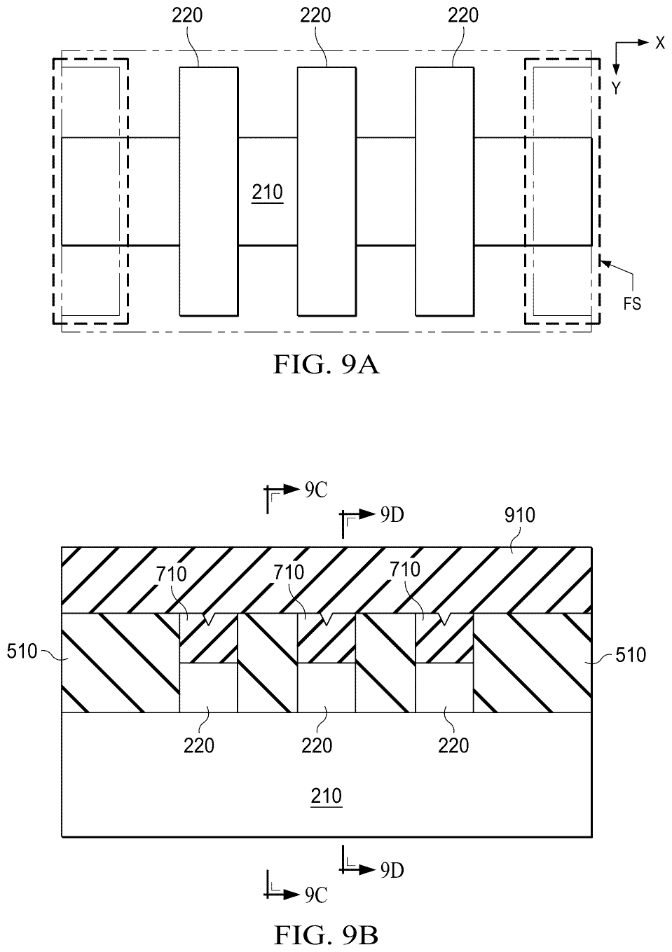

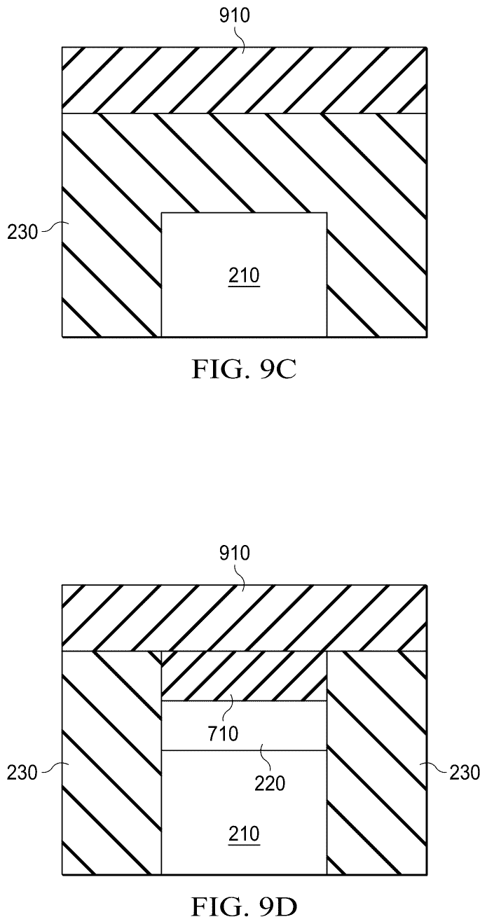

FIGS. 9A-9D show deposition of insulator layer 910. FIG. 9A is a top down view. FIGS. 9B-9D are cross section views. Insulator layer 910 covers simulated inner spacer layer 710.

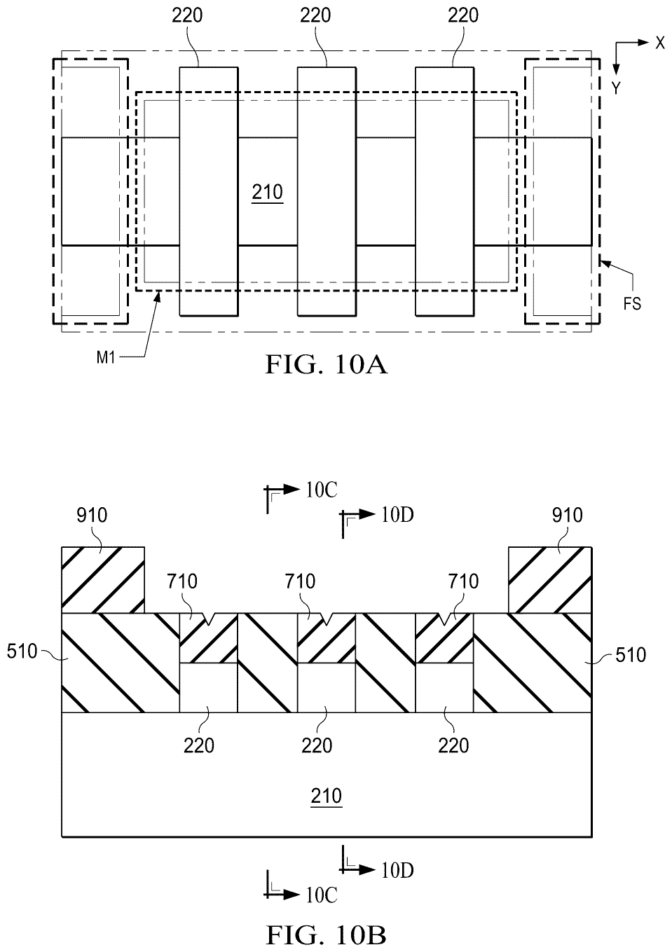

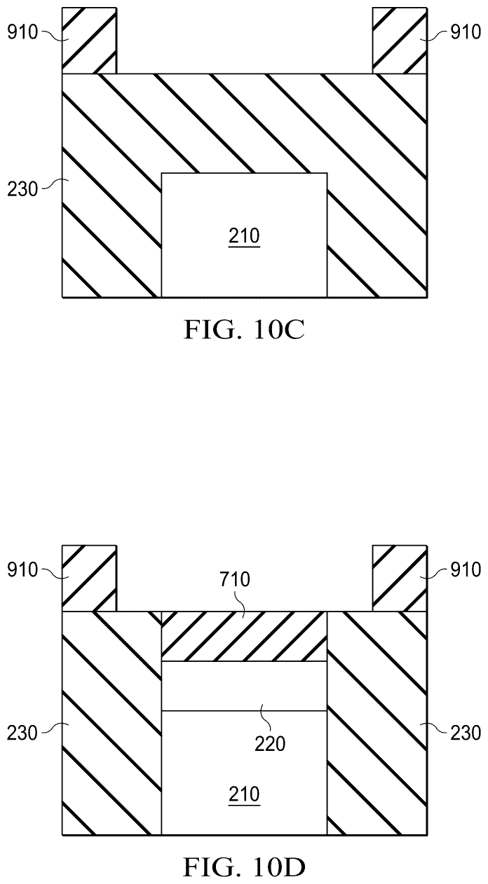

FIGS. 10A-10D show a metal open process step by patterning insulator layer 910. FIG. 10A is a top down view. FIGS. 10B-10D are cross section views. The indents of each pedestal are exposed.

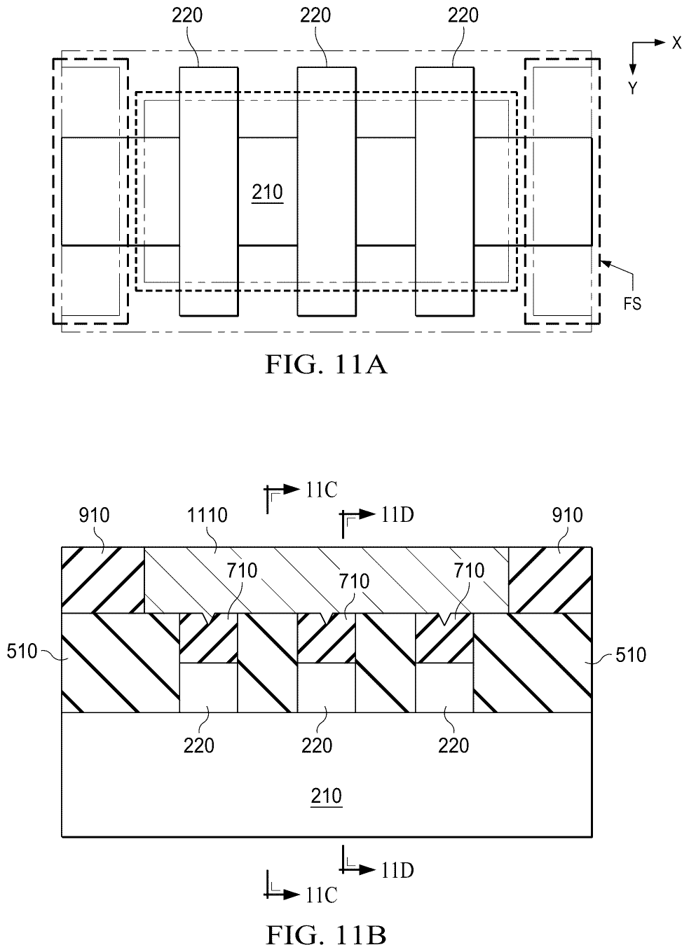

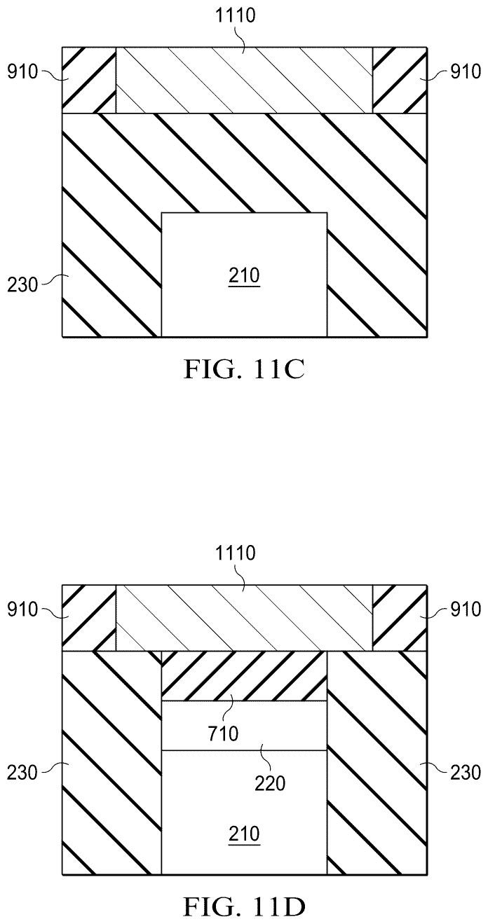

FIGS. 11A-11D show metal fill by depositing metal layer 1110. FIG. 11A is a top down view. FIGS. 11B-11D are cross section views. Metal layer 1110 fills the indents of each pedestal.

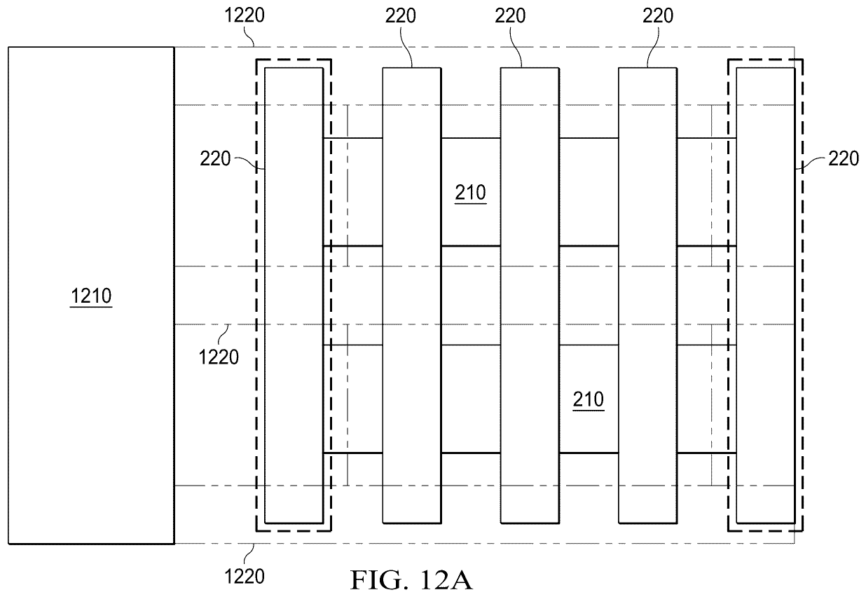

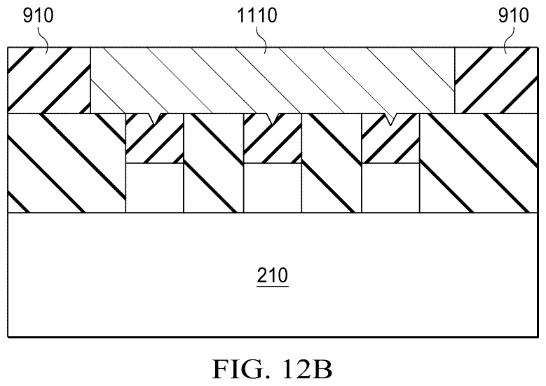

FIGS. 12A-12B show (12A) a top down view of wiring for electrical testing and (12B) a cross section view of the simulated inner spacer reliability evaluation component shown in FIGS. 11B-11D. Pad 1210 is electrically connected to conductors 1220. This embodiment of wiring can be coupled to and characterize two components.

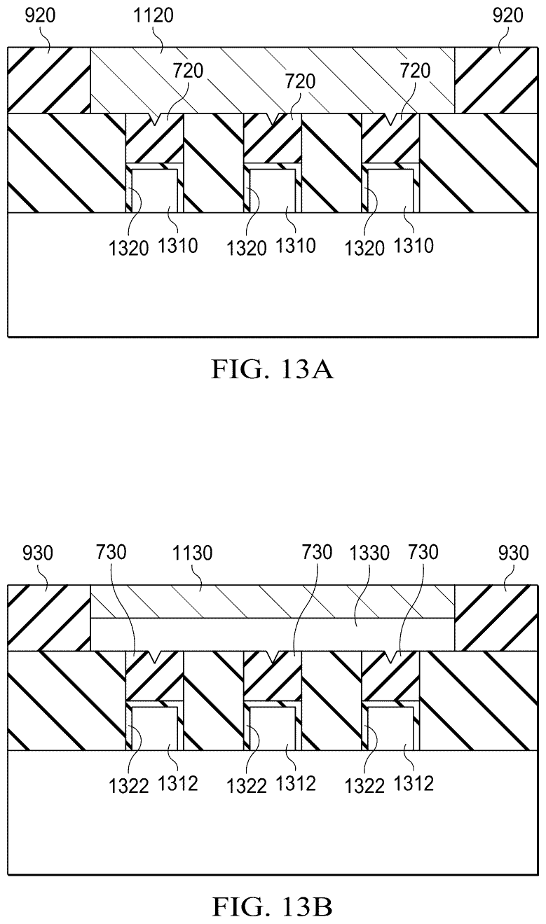

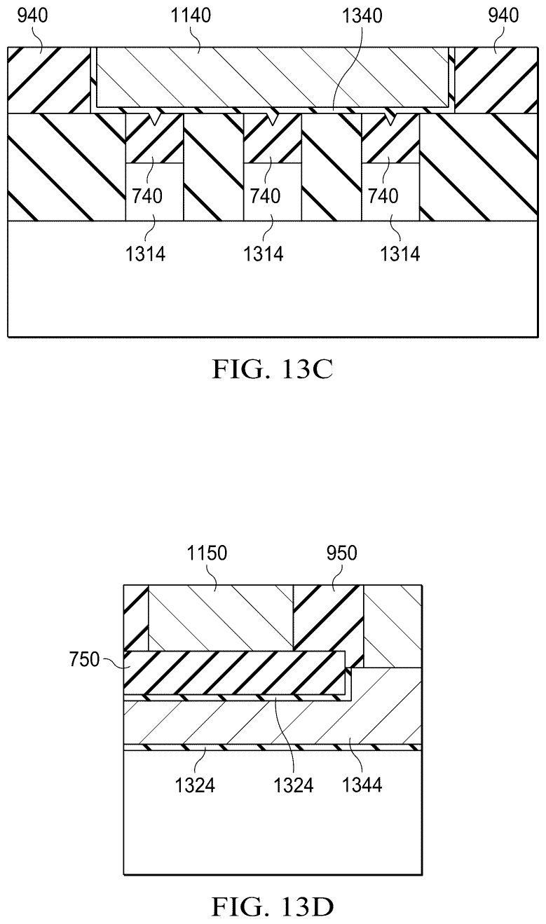

FIGS. 13A-13D show cross sectional views of alternative embodiments of simulated inner spacer reliability evaluation components. Referring to FIG. 13A, this embodiment includes a pinched off simulated inner spacer 720 with metal 1120 on top and a high K dielectric 1320 coated work function metal 1310 on the bottom. Insulator 920 is adjacent metal 1120. Referring to FIG. 13B, this embodiment includes a pinched off simulated inner spacer 730 with a doped a-Si layer 1330 beneath metal 1130 on the top and a high K dielectric 1322 coated work function metal 1312 on the bottom. Insulator 930 is adjacent metal 1130. Referring to FIG. 13C, this embodiment includes a pinched off simulated inner spacer 740 with a high K dielectric 1340 coated work function metal 1140 on top and SiGe pedestal 1314 on the bottom. Insulator 940 is adjacent the high K dielectric 1340 coating of metal 1140. Referring to FIG. 13D, this embodiment is depicted (relative to the previous 3 embodiments) from the right-hand side and includes a pinched off simulated inner spacer 750 having contact with insulator 950. Beneath the pinched off simulated inner spacer 750 is work function metal pedestal 1344 that is coated with high K dielectric 1324. Insulator 950 is adjacent metal 1150.

The flowchart and block diagrams in the Figures illustrate the architecture, functionality, and operation of possible implementations of systems and methods according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. But the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C,” may include item A, item A and item B, or item B. This example also may include item A, item B, and item C, or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A simulated inner spacer reliability evaluation component, comprising:
a substrate having a surface;
at least one pedestal coupled to the surface of the substrate;
at least one pinched off simulated inner spacer coupled to the at least one pedestal, wherein the at least one pinched off simulated inner spacer defines at least one indent located above the at least one pedestal; and
a metal layer coupled to the at least one pinched off simulated inner spacer.

2. The simulated inner spacer reliability evaluation component of claim 1, further comprising a dielectric layer coupled to the surface of the substrate and adjacent to both the at least one pedestal and the at least one pinched off simulated inner spacer.

3. The simulated inner spacer reliability evaluation component of claim 2, wherein the dielectric layer comprises SiO₂.

4. The simulated inner spacer reliability evaluation component of claim 2, further comprising an insulator layer coupled to the dielectric layer and adjacent to the metal layer.

5. The simulated inner spacer reliability evaluation component of claim 4, wherein the insulator layer comprises SiBCN.

6. The simulated inner spacer reliability evaluation component of claim 1, wherein the pinched off simulated inner spacer comprises SiN.

7. The simulated inner spacer reliability evaluation component of claim 1, wherein the pedestal comprises SiGe.

8. The simulated inner spacer reliability evaluation component of claim 1, wherein the metal layer comprises tungsten.

9. The simulated inner spacer reliability evaluation component of claim 1, wherein the at least one pedestal comprises a work function metal and at least a portion of the work function metal is coated with a high K dielectric.

10. The simulated inner spacer reliability evaluation component of claim 9, further comprising a doped a-Si layer located between the at least one pinched off simulated inner spacer and the metal layer.

11. The simulated inner spacer reliability evaluation component of claim 4, wherein at least a portion of the at least one pinched off simulated inner spacer is in contact with the insulator layer.

12. The simulated inner spacer reliability evaluation component of claim 1, wherein the pedestal comprises SiGe and the metal layer is at least partially coated with a high K dielectric.

13. A method of forming a simulated inner spacer reliability evaluation component, the method comprising:
providing a substrate having a surface and a pedestal layer coupled to the surface of the substrate;
patterning the pedestal layer;
depositing a dielectric layer on the surface of the substrate, wherein the dielectric layer is adjacent the patterned pedestal layer;
etching back the patterned pedestal layer to form at least one pedestal;
depositing a simulated inner spacer layer on both the dielectric layer and the etched back patterned pedestal layer;
etching back the simulated inner spacer layer, wherein the etched back simulated inner spacer layer comprises at least one pinched off simulated inner spacer comprising at least one indent located above the at least one pedestal;
depositing an insulating layer on both the dielectric layer and the at least one pinched off simulated inner spacer;
patterning the insulating layer to expose the at least one pinched off simulated inner spacer; and
depositing a metal layer above the exposed at least one pinched off simulated inner spacer.

14. The method of claim 13, wherein the at least one pedestal comprises a work function metal and at least a portion of the work function metal is coated with a high K dielectric.

15. The method of claim 14, further comprising depositing a doped a-Si layer above the exposed at least one pinched off simulated inner spacer before depositing the metal layer above the exposed at least one pinched off simulated inner spacer.

16. The method of claim 14, wherein at least a portion of the at least one pinched off simulated inner spacer is in contact with the insulator layer.

17. The method of claim 13, wherein the pedestal comprises SiGe and the metal layer is at least partially coated with a high K dielectric.

18. The method of claim 13, further comprising connecting a wiring pad to the metal layer for electrical testing of the at least one pinched off simulated inner spacer.

19. A simulated inner spacer reliability evaluation component, comprising:
a substrate having a surface;
at least one pedestal coupled to the surface of the substrate;
at least one pinched off simulated inner spacer coupled to the at least one pedestal, wherein the at least one pinched off simulated inner spacer defines at least one indent located above the at least one pedestal, and wherein the pinched off simulated inner spacer comprises SiN;
a metal layer coupled to the at least one pinched off simulated inner spacer;
a dielectric layer coupled to the surface of the substrate and adjacent to both the at least one pedestal and the at least one pinched off simulated inner spacer, wherein the dielectric layer comprises SiO₂; and
an insulator layer coupled to the dielectric layer and adjacent to the metal layer, wherein the insulator layer comprises SiBCN.

20. The simulated inner spacer reliability evaluation component of claim 19, wherein the at least one pedestal comprises a work function metal and at least a portion of the work function metal is coated with a high K dielectric.
